(19) United States
(12) Patent Application Publication
(10) Pub. No.: US 2009/0321247 A1
(43) Pub. Date: Dec. 31, 2009

(54) IONIZED PHYSICAL VAPOR DEPOSITION (iPVD) PROCESS

(75) Inventors: Frank M. Cerio, JR., Albany, NY (US); Jacques Faguet, Albany, NY (US); Bruce D. Gittleman, Englewood, CA (US); Rodney L. Robison, East Berne, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 12/555,068

(22) Filed: Sep. 8, 2009

Related U.S. Application Data
(63) Continuation-in-part of application No. 10/811,326, filed on Mar. 26, 2004.
Application No. 10/811,326 is a continuation-in-part of application No. 10/795,093, filed on Mar. 5, 2004.
Application No. 10/795,093 is a continuation-in-part of application No. 11/091,741, filed on Mar. 28, 2005.
Application No. 11/091,741 is a continuation-in-part of application No. 11/279,039, filed on Apr. 7, 2006.

(51) Int. Cl. C23C 14/34

(52) U.S. Cl. 204/192.11

(57) ABSTRACT

A method is provided of operating a deposition system to deposit coating material into high aspect ratio nano-sized features on a patterned substrate that enhances sidewall coverage compared to field area and bottom surface coverage while minimizing or eliminating overhang. The method includes performing a process step with a gross field area deposition rate of about 25 to 70 nm/min and simultaneously etching the barrier layer to establish a net field area deposition rate of about 5 to 40 nm/min. The method may also include first performing a protective layer deposition step with a field area deposition rate of about 5 to 20 nm/min without etching the underlying surface then performing a surface modification step with gross deposition and simultaneous etching at a field modification net deposition rate of about −10 to +40 nm/min.

This application is a continuation-in-part of U.S. patent application Ser. Nos. 10/811,326 filed on Mar. 26, 2004, 10/795,093 filed on Mar. 5, 2004, 11/091,741 filed Mar. 28, 2005, and 11/279,039 filed Apr. 7, 2006, the disclosures of which are hereby expressly incorporated herein by reference. This application is also related to U.S. patent application Ser. No. 10/138,049, now U.S. Pat. No. 6,755,945, the disclosure of which is also incorporated herein by reference.

### FIELD OF THE INVENTION

The invention relates to the metallization of via and trench structures on semiconductor wafers. More particularly, the invention relates to the metallization of high aspect ratio via and trench structures of silicon wafers utilizing ionized sputtered materials to form barrier and seed layers on the substrates.

### BACKGROUND OF THE INVENTION

In the metallization of high aspect ratio vias and trenches on semiconductor wafers, it is required that the barrier and seed layer have good sidewall coverage. The barrier layer needs to be as thin as possible without sacrificing its barrier properties. The barrier layer must be thin because of its electrical resistance, which adds to the electrical resistance of the interconnect pattern of the electrical device. The barrier layer also needs to be conformal and continuous to prevent diffusion of the seed layer material into the dielectric layer or other layers, which can lead to reliability problems. Thus, the barrier layer thickness must be well-controlled and minimized, especially at the bottom of the features.

Metallization can occur within an Ionized Physical Vapor Deposition (iPVD) system, which provides good sidewall and bottom coverage in via and trench structures. However, as the geometries shrink to 0.15 micrometers and less, the control of the deposition of the barrier layer becomes more critical. For example, during barrier layer deposition, there is a tendency for an overhang to form at the top edge of the feature's entrance due to buildup of material there, leading to defects in the filling of the feature.

FIG. 1 illustrates a simplified view of a patterned substrate 10 that is being processed and the resultant buildup of material. The patterned substrate 10 can be a semiconductor wafer 14 having at least one feature 18, such as a via or trench, formed therein. The feature 18 includes a field area 22, at least one sidewall 26, and at least one bottom surface 30. The field area 22 refers to an upper surface of the patterned substrate 10 that is being processed and is the surface into which high-aspect ratio features 18 extend. Though only one feature 18 is shown, it would be understood that the patterned substrate 10 can include one or more features 18. Each feature 18 of the patterned substrate 10 can be less than 130 nm in width.

The patterned substrate 10 is shown having a plurality of metal ions 32 impacting the patterned substrate 10 and depositing a field barrier layer 34 on the field area 22, a sidewall barrier layer 35 on the sidewalls 26, and a bottom barrier layer 36 on the bottom surface 30. As the plurality of metal ions 22 are deposited onto the patterned substrate 10, the barrier layer 34 has a propensity to become thicker at the via entrance causing an overhang structure 38. Similarly, the deposition of metal on the bottom surface 30 of the feature 18 can become thicker than at the sidewalls 26. This overhang structure 38 interferes with the subsequent deposition of a seed layer onto the sidewalls 26 and the bottom surface 30 of the feature 18. Therefore, it is highly desirable to have an ionized PVD process where bottom and sidewall coverage is well balanced and overhang is minimized.

One process described in U.S. patent application Ser. No. 10/138,049, now U.S. Pat. No. 6,755,945, by Yasar et al., assigned to the assignee of the present application, provides an ionized PVD process including sequential deposition and etching. While this sequential deposition and etch process for removing the overhang structures is much improved over prior processes, some overhang can remain even after the etch sequence if the production of the overhang structures is not fundamentally controlled.

Additionally, the high bias powers that are used in a conventional deposition process to obtain sufficient sidewall coverage of not more than 6 nm can lead to damage on the field and/or bottom surface of the feature.

Accordingly, there is a need to control the deposition of the barrier layer while preventing the overhang that typically develops during the deposition step.

### SUMMARY OF THE INVENTION

The invention provides a method of operating an ionized physical vapor deposition (iPVD) system in which a patterned substrate is positioned on a wafer table within a processing chamber. The patterned substrate has a field area and one or more features each having at least one sidewall and at least one bottom surface. An inductively-coupled high-density plasma having a plurality of ions of a process gas is created in the processing chamber. Process gas ions sputter material from a target, ionize the sputtered material for deposition onto the patterned substrate, and simultaneously etch the deposited material from the patterned substrate as it is being deposited. This sputtering, ionizing, and etching occur simultaneously in a given subprocess or process step. Such a process may be referred to as a simultaneous dep/etch, or simultaneous IPVD/etch process step. In the process step, a barrier layer or a seed layer may be deposited. The process step deposits material at a low net deposition rate or at a rate in which approximately no net deposition occurs on the field area of the substrate.

In certain embodiments of the present invention, an initial process step is performed before the performance of the simultaneous dep/etch step to deposit a protective layer onto the patterned substrate with process parameters set to produce a sufficiently positive deposition rate that avoids etching of the substrate or an underlying layer of the substrate. In some such embodiments, parameters are set to deposit a protective layer in a deposition step that ensures that some deposited material is deposited without any etching of the layer on which the protective layer is being deposited. This protective layer covers all areas of the substrate that might be exposed to etching in a subsequent dep/etch process step, such as the field area and the feature bottom areas. This protective layer deposition step may be accomplished by adjusting parameters, particularly a substrate bias power, such that ions will not be energized to impact the substrate at or above the sputter threshold of the underlying substrate or layer on which the protective layer is being deposited.

Also, depending on the relative sputter thresholds of the material being deposited and the underlying layer, other embodiments may be possible in which parameters can be set to perform an initial simultaneous deposition and etch process step. In such embodiments, material would be simultaneously deposited and etched such that at least some of the material is deposited onto the field area of the substrate without etching of an underlying layer on the field area occurring. In still other such embodiments, parameters are set to perform a surface modification process step in which material is deposited over a protective layer and simultaneously etched without penetrating the underlying protective layer to the point of etching the substrate.

In one illustrative embodiment, the present invention is directed to a method of operating an ionized physical vapor deposition system. The method includes positioning a patterned substrate on a wafer table that is within a vacuum processing chamber and that is opposite a target of a layer material. The patterned substrate includes a field area and one or more features each having at least one sidewall and at least one bottom surface. A surface modification process is then performed by creating an inductively-coupled high-density plasma having a plurality of ions of a process gas. The inductively-coupled high-density plasma sputters the layer material from the target, ionizes the sputtered layer material for deposition onto the patterned substrate, and etches the barrier layer material from the patterned substrate. Performing the surface modification process includes establishing a chamber pressure that is greater than about 5 mTorr and less than about 15 mTorr and maintaining a substrate bias power that is effective to establish a gross deposition rate that is greater than about 25 nm/min and less than about 70 nm/min on the field area of the patterned substrate while simultaneously etching the deposited layer material from the field area to establish a field modification net deposition rate of greater than about −10 nm/min and less than about +40 nm/min.

In another illustrative embodiment, the present invention is directed to a method of operating an ionized physical vapor deposition system. The method includes positioning a patterned substrate on a wafer table that is within a vacuum processing chamber and that is opposite a target of a coating material. The patterned substrate includes a field area and one or more features each having at least one sidewall and at least one bottom surface. An inductively-coupled high-density plasma having a plurality of ions of a process gas is created in the processing chamber. The process gas ions sputter coating material from the target, ionize the sputtered coating material for deposition onto the patterned substrate, and etch the deposited coating material from the patterned substrate. A protective layer deposition process is performed by establishing a chamber pressure of greater than about 55 mTorr and less than about 100 mTorr and adjusting the substrate bias power during the sputtering to establish a field deposition rate on the field area of the patterned substrate that is greater than about 5 nm/min and less than about 30 nm/min. A surface modification process is then performed by establishing a chamber pressure that is greater than about 5 mTorr and less than about 15 mTorr and maintaining a substrate bias power that is effective to establish a field modification net deposition rate of greater than about −10 nm/min and less than about +40 nm/min on the field area of the patterned substrate.

In a specific embodiment of the process, a tantalum (Ta) and tantalum nitride (TaN) barrier layer is deposited over a low-K dielectric on a patterned substrate. A protective layer of TaN is first deposited in a low net deposition step in which bias power is set to produce bias potential below the sputter threshold of the underlying dielectric layer. An ultra-thin TaN barrier layer may be deposited using a very low deposition rate process as described in U.S. patent application Ser. No. 11/279,039, filed Apr. 7, 2006, and expressly incorporated by reference herein. The process is an IPVD process that produces a high ion fraction of sputtered tantalum in a high density plasma containing nitrogen that is controlled to produce a high nitrogen to tantalum ratio layer without nitriding the tantalum target. A surface modification layer of tantalum is then deposited over the protective layer by a simultaneous dep/etch process step that completes coverage of the sidewalls to complete the barrier layer. A copper seed layer may then be deposited over the barrier layer with bias power and other parameters set to perform a simultaneous dep/etch step to deposit copper on the bottom and sidewalls of the features, with the bias set above the sputter threshold of the underlying barrier layer so that no etching of the barrier layer will occur. Then further deposition of the copper may be carried out by a further copper deposition step.

These and other objectives and advantages of the present invention will be apparent from the following detailed description of the drawings and the exemplary embodiments.

### BRIEF DESCRIPTION OF THE DRAWINGS

A more complete appreciation of various embodiments of the invention and many of the attendant advantages thereof will become readily apparent with reference to the following detailed description, particularly when considered in conjunction with the accompanying drawings, in which:

FIG. 1 illustrates a simplified view of a patterned substrate, shown in cross-section and in accordance with one embodiment of the present invention.

FIG. 2 illustrates an exemplary block diagram of a deposition system in accordance with one embodiment of the present invention.

FIG. 2A illustrates an enlarged cross-sectional diagram of a target and permanent magnet pack arrangement.

FIG. 3 illustrates a simplified flow diagram of a method of operating the deposition system in accordance with one embodiment of the present invention.

FIGS. 4A-4D illustrate a schematic representation of an exemplary process in accordance with one embodiment of the present invention.

FIGS. 5A-5E illustrate a schematic representation of another exemplary process in accordance with another embodiment of the present invention.

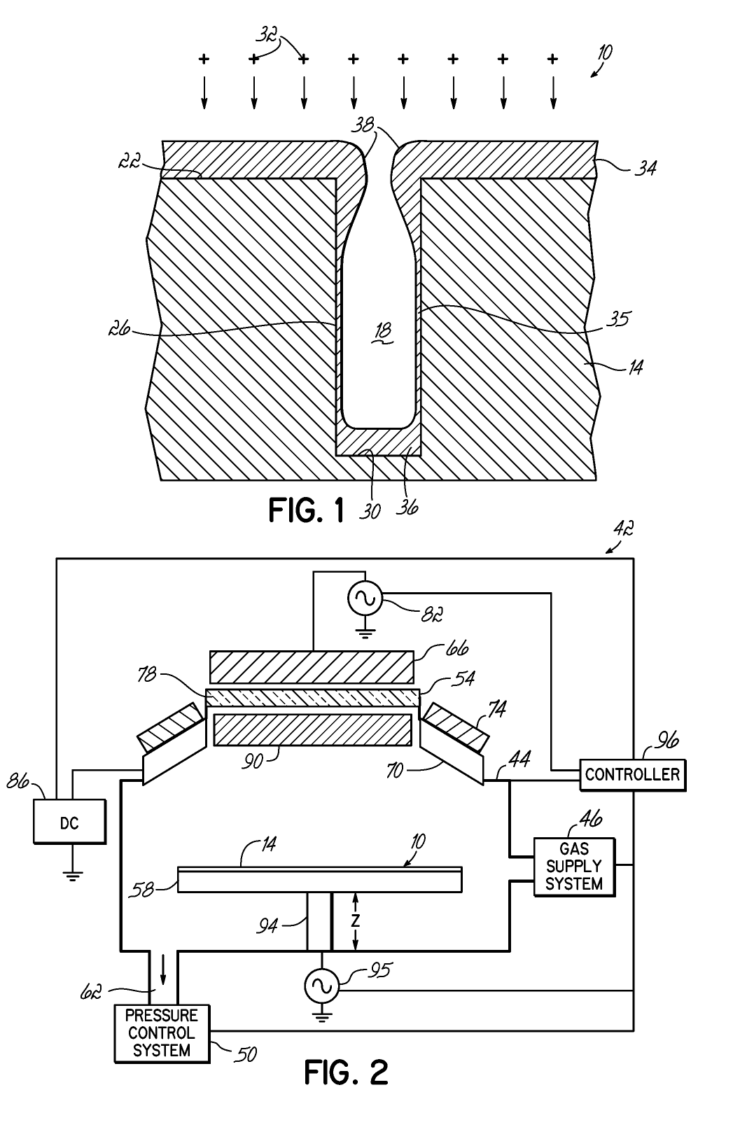

### DETAILED DESCRIPTION OF SEVERAL EMBODIMENTS

The embodiments of the present invention provide a method of operating a deposition system to deposit material into nano-features on a patterned substrate 10. The methods can be used, for example, to deposit a barrier layer material using a protective layer deposition process, wherein a bias on the wafer table 58 is adjusted to establish an ultra-low deposition rate in a field area 22 of the patterned substrate 10 that avoids etching of the underlying surface on which the protective layer is being deposited. The method can also be used, for example, to perform a surface modification process, wherein the bias on the wafer table 58 is adjusted to establish simultaneous deposition and etching of the barrier layer material on the field area 22 of the patterned substrate 10.

The methods of the present invention can be performed in any appropriate deposition system, including an Ionized Physical Vapor Deposition (iPVD) system. The general concepts of the iPVD system are described in U.S. Pat. No. 6,287,435, the disclosure of which is incorporated herein, in its entirety, by reference.

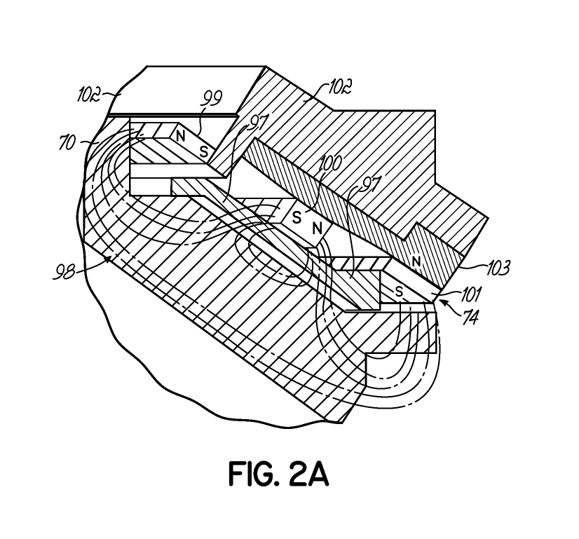

As shown in FIG. 2, the iPVD system 42 comprises an iPVD processing chamber 44 having various system components, including a gas supply system 46 coupled to the processing chamber 44, a pressure control system 50 coupled to the processing chamber 44 through an exhaust port 62, a processing module 54 coupled to the processing chamber 44, and a wafer table 58 within the processing chamber 44.

The iPVD system 42 also includes a controller 96 that is coupled to the various system components. The controller 96 can include a microprocessor, a memory (e.g., volatile or non-volatile memory), and a digital I/O port that are capable of generating control voltages sufficient to communicate with the system components. Moreover, the controller 96 can include a program that is stored in the memory and utilized to control the aforementioned system components of the iPVD system 42. The program can include a process recipe for a particular operational process. The communication between the controller 96 and the various system components can include active inputs to one or more of the various system components regarding operational control and/or outputs from one or more of the various system components regarding operational process and/or status or both. The outputs can be compared to a target process and/or status that are defined by the process recipe. The controller 96 can also be configured to analyze the process and/or status data, to compare the process and/or status data with historical process and/or status data, and/or to use the comparison to predict, prevent, and/or declare a fault.

The iPVD processing module 54 includes an antenna 66, a window 78 coupled to the antenna 66, a louvered deposition baffle 90 coupled to the window 78, a target 70, and a permanent magnet pack 74 coupled to the target 70. RF power can be supplied to the antenna 66 from the RF generator 82 to create an inductively-coupled plasma in the chamber 44. The permanent magnet pack 74 can be located behind the target 70 and can be used to produce a magnetic tunnel over the target 70 for magnetron sputtering.

The antenna 66 can be positioned outside of the chamber 44 behind the dielectric window 78. The louvered deposition baffle 90, preferably formed of a slotted metallic material, is located inside of the chamber 44 closely spaced from the window 78 to shield the window 78 from deposition. The controller 96 can be used to determine the amount of RF power to provide and when to have it applied to the antenna 66. For example, RF power from the RF generator 82 to the antenna 66 can be switched between different power levels during the deposition process.

The operating frequency for the RF generator 82 can range from 1 MHz to 100 MHz. For example, an operating frequency of about 13.56 MHz can be used. Alternately, other frequencies can be used.

The material for the deposition process is supplied from the target 70. Suitable target materials can include tantalum (Ta), or ruthenium (Ru); however, other materials can include iridium (Ir), aluminum (Al), silver (Ag), copper (Cu), or lead (Pb).

A DC power source 86 is coupled to the target 70 and supplies a DC power to the target 70. The DC power level is adjustable to at least partially control the sputtering of material from the surface of the target 70. For example, when the DC power to the target 70 is reduced or turned off, then the sputtering of target material is substantially reduced or stopped, respectively.

The controller 96 can be used to determine the amount of DC power to provide and when to have it applied to the target 70. After a certain desired amount of deposition, the DC power to the target 70 is reduced or turned off to substantially reduce or stop the deposition process. In some cases, the deposition process can be substantially reduced and/or stopped by reducing the DC power level to a very low level without completely turning it off.

The wafer table 58 can be coupled to the processing chamber 44 using a Z-motion drive 94. The Z-motion drive 94 can be used to adjust the substrate-to-source distance to provide the best deposition uniformity, and the best coverage and symmetry of the sidewall 26 and bottom 30 of the feature 18. The controller 96 can be used to determine the target-to-substrate (TS) separation distances required during the deposition process and provide the control data to the Z-motion drive 94 when it is required.

The patterned substrate 10 can be transferred into and out of the processing chamber 44 through an opening (not shown) that is controlled by a gate valve assembly (not shown). In addition, the patterned substrate 10 can be transferred onto and off of the wafer table 58 using a robotic substrate transfer system (not shown). In addition, the patterned substrate 10 can be received by substrate lift pins (not shown) housed within the wafer table 58 and mechanically translated by devices housed therein. Once the patterned substrate 10 is received from the transfer system, it can be lowered to an upper surface of the wafer table 58.

During processing, the patterned substrate 10 can be held in place on top of the wafer table 58. For example, an electrostatic chuck (not shown) can be used as the wafer table 58. In addition, the wafer temperature can be controlled when the patterned substrate 10 is on the wafer table 58. For example, heating and/or cooling elements (not shown) can be used. The temperature of the patterned substrate 10 can be controlled to obtain the best via metallization. The controller 96 can be used to determine and control the temperature of the patterned substrate 10. In addition, the temperature can be controlled by providing the wafer table 58 with cooling fluid passages and the appropriate temperature controls. Good thermal contact between the wafer table 58 and the patterned substrate 10 can be achieved by providing backside gas conduction between the patterned substrate 10 and the wafer table 58. Backside gas pressure can be controlled during the deposition steps to ensure that thin metal deposition, especially at the sidewalls 26 of the features 18, is not agglomerated.

Heat generated at the patterned substrate 10 during processing can be extracted efficiently by the wafer table 58 to keep the temperature of the patterned substrate 10 at substantially below room temperature, preferably below 0°, preferably to about −30° Celsius.

RF bias power can be supplied to the wafer table 58 using the RF bias generator 95. The RF bias power can be used to provide a wafer bias. The controller 96 can be used to determine the amount of RF bias power to provide and when to have it applied to the wafer table 58. For example, the RF bias power can be turned on to a level appropriate during deposition to provide a net negative bias on the patterned substrate 10 to improve and affect the process.

The operating frequency for the RF bias generator 95 can range from 1 MHz to 100 MHz. For example, an operating frequency of about 13.56 MHz can be used. Alternately, other frequencies can be used.

Process gas can be provided to the processing chamber 44 by the gas supply system 46. The process gas can be an inert gas or a reactive gas, or a combination thereof. A suitable inert gas is argon (Ar); however, other inert gases, such as helium (He), krypton (Kr), radon (Rn), and xenon (Xe), or a combination thereof, can also be used. The inert gas is ionized and forms a plasma within the processing chamber 44 in a manner that is described in detail below. When an alloy barrier layer material (for example, TaN) is desired, a reactive process is used where the gas supply system 46 supplies the reactive gas (for example, N₂) along with the inert gas to the processing chamber 44. The metal (for example, Ta) provided from the sputtered target material reacts with ions of the reactive gas at the surface of the patterned substrate 10. The reactive gas can include nitrogen or oxygen and, for example, can include N₂, NO, N₂O, NH₃, O₂, NO, N₂O, or H₂O.

Chamber pressure can be controlled using the pressure control system 50. For example, process gas can be supplied into the vacuum processing chamber 44 by the gas supply system 46. The chamber pressure can be maintained at a vacuum by the pressure control system 50. The controller 96 can be used to control the flow rate and chemistry for the process gas, and to control the chamber pressure accordingly.

The iPVD system comprises a serviceable module capable of providing features and operating conditions including the following: (1) base vacuum of less than 10⁻⁸ Torr, (2) operating inert gas pressure of between 30 and 130 mTorr, (3) provision for reactive gas at partial pressure of 0-50 mTorr, (4) variable TS spacing of 6 to 9 inches, (5) electrostatic chucking with backside gas heating or cooling, and (6) shielding that restricts deposition to removable, cleanable components with surfaces having good adhesion of sputtered material to prevent particle generation.

In operation, the inert gas is provided to the chamber 44. The RF power source 82 is activated, which inductively couples to and ionizes the inert gas into a sputtering plasma. The sputtering plasma is trapped under the field of the permanent magnet pack 74 at the surface of the target 70 and sputters coating material from the target 70. The sputtered coating material enters the region of the processing space above the patterned substrate 10, which is occupied by the dense secondary plasma. While in the secondary plasma, electrons are stripped from the sputtered coating material to form positive ions of the coating material. A negative bias voltage is applied to the patterned substrate 10 on the wafer table 58, which attracts the positive ions of sputtering material from the region of the secondary plasma toward and onto the surface of the patterned substrate 10, with the angles of incidence approximately being perpendicular to the patterned substrate 10. In this way, the positive ions can enter the features 18 on the patterned substrate 10 to coat the bottom surfaces 30.

During a typical iPVD process, the magnet field strength of the permanent magnet pack 74 near the target 70 is expected to increase electron confinement adjacent the target 70, thereby increasing the number of localized ions and increasing the sputtering rate. When a high density plasma is available, the trapping of electrons around the target 70 by the magnet pack 74 is less important for the generating of ions of the process gas. Therefore, the sputtering rate of material from the target 70 is less dependent on the local static magnetic field, leaving a desirable target 70 erosion pattern as the main reason for maintaining a local static magnetic field. During a typical plasma etch, the high plasma density produced by the antenna 66 along with the bias power on the patterned substrate 10 determines the etching rate. However, when the two operations, iPVD and etching, are combined in one process chamber 44, the effects of the static magnetic field produced by the portion of the processing module 54 can negatively interact with the portion of the iPVD system 42 that is responsible for etching. This negative interaction is the result of confining the electrons produced by the inductively-coupled plasma and the centralizing of the plasma profile. Static magnetic fields can have a negative effect on ICP source uniformity due to peripheral plasma confinement, which reduces diffusive radial loss.

To achieve a balance between the two systems and to effectively produce a simultaneous deposition and etch apparatus that produces a uniform film on the substrate and uniform feature coverage, the processing system can accommodate either a reduced or no static magnetic field strength in the vicinity of the target surface. A weak magnet configuration can maintain the static magnetic field shape and orientation of the stand-alone iPVD equipment, so that the field near the target 70 and the nearby plasma generates an optimal erosion profile for high target utilization. This has an impact on target lifetime and utilization as well as on deposition uniformity. Accordingly, the permanent magnet pack 74 produces a static magnetic field of at least 20 Gauss at the target surface and not more than about 10 Gauss. More preferably, a magnetic field ranging from about 5 Gauss to about 10 Gauss at the target surface can aid in eliminating this confinement effect.

Various manners of adjusting the static magnetic field strengths within the iPVD system 42 have been described in U.S. patent application Ser. No. 10/795,093. One such magnet pack, shown in greater detail in FIG. 2A, is positioned behind a target 70. A target backing plate and cooling jacket 97, formed of stainless steel or other non-magnetic material, lies between the magnet pack 74 and the back of the target 70.

The magnet pack 74 includes a magnet configuration 98 of an inner ring magnet 99, a center ring magnet 100, and an outer ring magnet 101. Each of the magnets 99, 100, 101 can be formed of a plurality of magnet segments ½ inch in width around the circumference of the magnet pack 74. The segments of the inner ring magnet 99 are ⅜ inch long in the direction parallel to the sputtering surface of the target 70, which is the orientation of the polar axis of the inner ring magnet 99. The inner ring magnet 99 is illustrated with the N-pole facing inward toward the axis of the target 70. The thickness of the inner ring magnet 99, the direction perpendicular to the surface of the target 70, is 4 mm.

The segments of the center ring magnet 100 are also ⅜ inch long in the direction parallel to the sputtering surface of the target 70, which is also the orientation of the polar axis of the center ring magnet 100. The center ring magnet 100 is illustrated with its S-pole facing inward toward the axis of the target 70. The thickness of the center ring magnet 100, the direction perpendicular to the surface of the target 70, is ¼ inch. The segments of the outer ring magnet 101 are ½ inch long in the direction parallel to the sputtering surface of the target 70, which is perpendicular to the orientation of the polar axis of the outer ring magnet 101. The outer ring magnet 101 is illustrated with its S-pole facing toward the target 70. The thickness of the outer ring magnet 101, the direction perpendicular to the surface of the target 70, is 4 mm.

The pole designations N and S can be the opposite of those described above. Further, the dimensions given above produce satisfactory magnets, but other configurations and dimensions can be designed to produce a static magnetic field that will satisfy the objectives of the invention.

The magnet pack 74 also includes a soft-iron magnetic yoke 102 at the back thereof, which can include the same yoke used with the magnet pack of U.S. Pat. No. 6,458,252. The magnetic yoke 102 can be supplemented by providing a soft-iron magnetic-material insert 103 to conform to the magnets 99, 100, 101, which are smaller than those of the patent. Because the magnets 99, 100, 101 are weaker than those of the patent, the thickness of the yoke 102 in the direction perpendicular to the surface of the target 70 can be reduced.

The iPVD system provides the following features and properties: (1) requires minimum operator effort and the smallest possible set of tools to perform routine tasks, (2) provides separation of RF and DC power from water to the best extent possible, (3) provides relative simplicity of design and operation, (4) allows rapid repair or replacement of the source including quick replacement of the whole internal source assembly, (5) provides modular internal assemblies, and (6) maintains RF shielding integrity to prevent leakage of radiation into the operating environment.

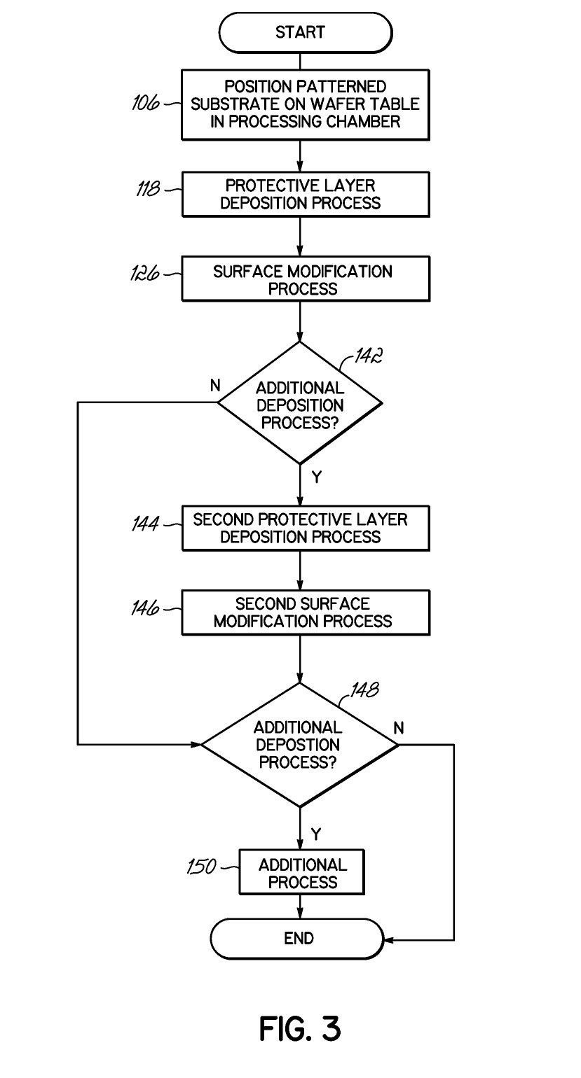

With the iPVD system 42 described with some detail, the steps of an exemplary method of depositing the coating material, such as a barrier layer, in accordance with one embodiment of the present invention, can be described with reference to FIGS. 3-5E.

FIG. 3 illustrates a simplified flow diagram of a method of operating the iPVD deposition system in accordance with one embodiment of the present invention. While the illustrative embodiments include an iPVD system, other types of deposition chambers can also be used, such as PVD chambers, CVD chambers, and PECVD chambers. In one embodiment, the protective layer deposition process can be used to deposit a barrier layer, such as a metal barrier layer.

In step 106 the patterned substrate 10 can be positioned on a wafer table 58 in a processing chamber 44. Alternately, a non-patterned substrate/wafer can be used. Once the processing chamber 44 is closed, a first process can be performed. In one embodiment, the first process includes a protective layer deposition process 118 to deposit a metal barrier layer on the patterned substrate 10.

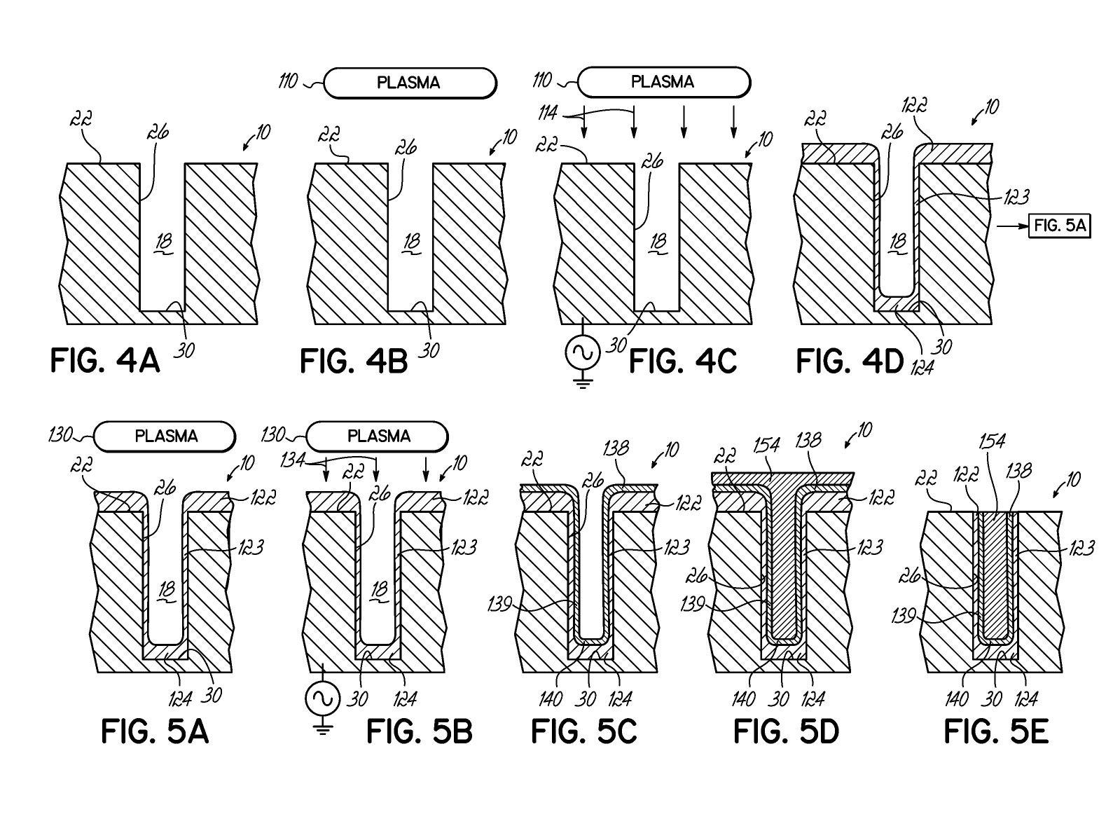

To perform the protective layer deposition process of step 118, the chamber pressure is adjusted to greater than about 1 mTorr and less than about 100 mTorr, more preferably ranging from about 55 mTorr to about 75 mTorr. The process gas, including an inert gas (for example, Ar) is supplied to the processing chamber 44 from the gas supply system 46 while the pressure control system 50 maintains the desired chamber pressure, as schematically shown in FIG. 4A.

While the flow of gas from the gas supply system 46 will depend largely on the desired chamber pressure and the operation of the vacuum of the pressure control system 50, the flow of gas can range from about 200 sccm to about 700 sccm. Accordingly, for a TaN barrier layer, the flow of N₂ can range from about 10 sccm to about 50 sccm, with the flow of Ar adjusted accordingly.

By applying the RF power to the antenna 66, RF energy inductively couples to and ionizes the inert gas into a plasma 110 above the patterned substrate 10, as shown in FIG. 4B.

The RF power to the target 70 is then activated such that sputtering of the target material can begin. The magnet tunnel surrounding the surface of the target 70 directs the distribution of the sputtering from the surface of the target 70 into the plasma 110. Once the sputtered target material is within the plasma 110, it can be ionized to form a plurality of positively charged metal ions 114, as shown in FIG. 4C.

Deposition of the barrier layer can now begin where more than about 30 Å and less than about 40 Å of the field barrier layer 34 being deposited onto the field area 22 of the patterned substrate 10. By controlling the deposition of the field barrier layer 34 onto the field area 22, the deposition of the bottom barrier layer 36 onto the bottom surface 30 is also controlled, which prevents the thickened deposition of the barrier layer on the bottom surface 30 and at the overhang 38.

FIGS. 4C-D illustrate that the controlled deposition of the field barrier layer 122, sidewall barrier layer 123, and bottom barrier layer 124 can be accomplished by adjusting the substrate bias power supplied from the RF bias generator 95 to the patterned substrate 10 to create the negative bias onto the patterned substrate 10. This negative bias draws the plurality of positively charged metal ions 114 from the plasma 110 and toward the surface of the patterned substrate 10 to provide a gross deposition rate onto the field area 22 that is greater than 5 nm/min and less than 30 nm/min. The metal ions 114 impact the surface of the patterned substrate 10 with angles of incidence that are about perpendicular to the patterned substrate 10. This allows the metal ions 114 to enter the feature 18 of the patterned substrate 10 and impact the bottom surface 30 while producing substantially no overhanging at openings of the feature 18, as shown in FIG. 4D. At this pressure range in an iPVD system, suitable substrate bias power for the barrier layer deposition can be less than about 1 kW.

At least one of the chamber temperature, the substrate temperature, the process gas chemistry, the process gas flow rate, the target material, the RF power, the substrate position, the target power, and the substrate bias power can be adjusted to establish the protective layer deposition rate in the field area 22 of the patterned substrate 10. The DC power supplied to the target 70 during the protective layer deposition process can range from about 10 Watts to about 2 kW. For an RF power source driving a 13.56 MHz ICP source, the RF power can range from about 2 kW to about 10 kW. When appropriate, a back-side pressure can also be used. At wafer table temperatures of about 10° C., the back-side pressure can range from about 4 Torr to about 20 Torr, but is preferably 6 Torr.

The protective layer deposition process can operate for a process time ranging from about 0 seconds to about 500 seconds, preferably about 30 seconds.

Measurement data can be obtained during the protective layer deposition process and used to determine when to stop the process. Measurement data can include chamber pressure data, chamber temperature data, substrate temperature data, process gas chemistry data, process gas flow rate data, target material data, ICP power data, substrate position data, target power data, substrate bias power data, processing time data, or process recipe data, or a combination thereof. In some cases the wafer can be removed from the processing chamber and measured in another chamber. For example, an optical digital profile (ODP) tool can be used. In addition, SEM data and/or TEM data can be used.

With the protective layer deposition process complete, a surface modification process 126 can now be performed. In some embodiments, the surface modification process can be performed in the same processing chamber as the protective layer deposition process. Alternately, the surface modification process can be performed in a different processing chamber. When the surface modification process step 126 is performed in a different chamber, the patterned substrate can be positioned on a second wafer table with a second processing chamber.

The surface modification process can be used to deposit a modified field barrier layer 138 onto the field area 22, a modified sidewall barrier layer 139 onto the sidewall 26, and a modified bottom barrier layer 140 onto the bottom surface 30 of the patterned substrate 10. The modified field barrier layer 138 and the modified bottom barrier layer 140 are simultaneously deposited and etched.

Generally, the surface modification process can be used to deposit the modified field barrier layer at a field modification net deposition rate that ranges from about −10 nm/min to about +40 nm/min. As a result of this field modification net deposition rate, the modified sidewall deposition rate can range from about 0 nm/min to about +10 nm/min and the modified bottom deposition rate can range from about −10 nm/min to about +10 nm/min.

While the modified barrier layer material can be the same as the barrier layer material that was deposited during the protective layer deposition process, in some embodiments it can be desired to use a different barrier layer material during the surface modification process.

The pressure control system coupled to the processing chamber and the gas supply system are used to establish a surface modification chamber pressure during at least a portion of the surface modification processing time. The surface modification chamber pressure can range from about 1 mTorr to about 100 mTorr, and alternately, the surface modification chamber pressure can range from about 20 mTorr to about 70 mTorr. The flow of the process gas from the gas supply system 46 and the pressure control system 50 are adjusted accordingly.

FIG. 5A illustrates the formation of the plasma 130 in a manner that is similar to the methods described previously. Material from the target 70 (FIG. 2) can be sputtered into the plasma 130 and can be ionized to form a plurality of positively charged metal ions 134 within the plasma 130, as provided in detail above.

The substrate bias power can then be adjusted to establish the field modification rate. Control of the barrier layer deposition can be accomplished, as described previously, by adjusting the substrate bias power supplied from the RF bias generator 95 to the patterned substrate 10 to provide a gross deposition rate on the field area 22 of the patterned substrate 10 that is greater than about 25 nm/min and less than about 70 nm/min. However, during the surface modification process 126, the substrate bias power also provides simultaneous etching of the modified field barrier layer 138 from the field area 22 and modified bottom barrier layer 140 from the bottom surface 30. The result is a net deposition rate of barrier layer material that is greater than about −5 nm/min and less than about +40 nm/min on the field area 22. This will also cause a re-sputtering of the modified bottom barrier layer 140 from the bottom surface 30 to the sidewalls 26 as the modified sidewall barrier layer 139, shown in FIG. 5C. At this pressure range for an iPVD system, suitable substrate bias power can range from about 0.0 Watts to about 1 kW.

Again, additional parameters can also be adjusted to establish the surface modification process. The modified barrier layer deposition target power can range from about 10 Watts to about 2 kW. For an RF power source driving a 13.56 MHz RF source, the RF power can range from about 2 kW to about 10 kW.

The surface modification process can operate for a process time ranging from about 0 seconds to about 500 seconds, preferably about 5 seconds to about 15 seconds.

More recently it has been noted that the iPVD system can be operated during the surface modification process such that the simultaneous deposition and etching of the modified field barrier layer results in a net deposition of the modified field barrier layer. Accordingly, the deposition rate of the modified field barrier layer is greater than 25 nm/min and less than about 70 nm/min. Simultaneous etching removes the modified field barrier layer such that the modified field barrier layer is deposited at a net deposition rate that is greater than about 5 nm/min and less than 40 nm/min.

To achieve the simultaneous deposition and etching at these rates, the chamber pressure is adjusted to greater than about 5 mTorr and less than about 15 mTorr. The flow of the process gas from the gas supply system 46 and the pressure control system 50 are adjusting accordingly. Again, the plasma 130 is formed in a manner that is similar to the methods described previously. Material from the target 70 can be sputtered into the plasma 130 and the sputtered metal ionized within the plasma 130, as provided in detail above.

At this pressure range, a suitable substrate bias power for the surface modification process can be less than about 1 kW.

As described above, the other parameters can also be adjusted to establish this field modification net deposition rate. For example, the TS distance can vary, but from about 240 mm to about 255 mm is typically suitable; the RF power can vary from about 4 kW to about 5.25 kW; and the DC power can vary from about 0.5 kW to about 3 kW. When a back-side pressure is used, the back-side pressure can range from about 4 Torr to about 20 Torr, but is preferably 6 Torr.

The surface modification process can operate for a process time ranging from about 5 seconds to about 15 seconds.

In accordance with the surface modification process 126, more than about 1 Å and less than about 20 Å of the modified field barrier layer 138 is deposited onto the field area 22 of the patterned substrate 10.

In various embodiments, the surface modification process can be used to perform one or more of the following procedures: deposit a seed layer, repair a seed layer, deposit a barrier layer, and repair a barrier layer.

Measurement data can be obtained during the modification barrier layer in a manner that is similar to the methods described for the protective layer. A processing time can be used to determine when to stop the second process. Alternately, thickness data can be used to determine when to stop the second process.

At the completion of both the protective layer deposition process 118 and the surface modification process 126, less than about 100 Å of the modified field barrier layer 138 is deposited onto the field area 22, about 10 Å to about 60 Å of the modified sidewall barrier layer 139 is deposited onto the sidewalls 26, and about 0 Å to about 20 Å of the modified bottom barrier layer 140 is deposited onto the bottom surface 30 of the patterned substrate 10. In this way, the barrier layer thickness is minimally but uniformly deposited within the feature 18, thus reducing the resistance of the interconnect pattern.

Returning again to FIG. 3, once the surface modification process 126 is complete, there is a decision to include an additional deposition process 142. In one embodiment of the present invention, a second protective layer deposition process 144 and a second surface modification process 146 can begin. The second protective layer deposition process 144 and second surface modification process 146 can deposit the same barrier layer material as the first protective layer deposition and surface modification 118, 126; however, in some embodiments a second barrier layer material is used. For example, the first protective layer deposition and first surface modification processes 118, 126 can be used to deposit a TaN barrier layer while the second protective layer deposition and surface modification processes 144, 146 are used to deposit a Ta barrier layer. Accordingly, during the second protective layer deposition and surface modification processes 144, 146 the gas supply system 46 will not include the flow of a reactive gas into the processing chamber 44. As would be known, the flow of the process gas from the gas supply system 46 and the pressure control system 50 will be adjusted to maintain the appropriate chamber pressure. For example, during a protective layer deposition process 144 of a tantalum barrier layer, the chamber pressure can be preferably maintained between about 55 mTorr and about 75 mTorr. Further, it would be known by those skilled in the art to adjust the other operational parameters provided above to achieve and/or maintain the deposition rates.

In another embodiment, not specifically shown in FIG. 3, the second surface modification process 146 can occur without the preceding second protective layer deposition process 144.

In step 148, a query is performed to determine when to perform an additional deposition process. When a decision is made to perform an additional deposition process, the procedure continues in step 142. When the decision is to not perform an additional deposition process, the procedure continues to step 150.

In step 150, a query is performed to determine whether additional processes are to be performed in the same processing chamber or other processing chambers. For example, one or more processing chambers can be coupled to each other by a transfer system. Appropriate additional processes 150 can include a conventional deposition process, a conventional etching process, a polishing process, a cleaning process, a measurement process, a storing process, another protective layer deposition process and/or surface modification process, or an electroplating process, or a combination thereof. The additional process 150 can be performed in the same processing chamber as the protective layer deposition process 118 and/or the surface modification process 126. Otherwise, the patterned substrate 10 can be transferred to another processing chamber 44 for the additional process 150.

In the illustrated embodiment, FIGS. 5D-5E show the additional process 150 as including a deposition process to fill the feature 18 with a metal plug 154, which is then followed by a polishing process to remove the deposited layers from the field area 22. In some embodiments, the additional process 150 can include a deposition of a seed layer. Other appropriate processes can be used as desired and as would be known by one skilled in the art.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

### Example 1

For a deposition process where TaN was the barrier layer material, the processing chamber of an iPVD system was prepared to perform a TaN protective layer process with a Ta target and the following parameters:

TABLE 1

| | TaN Protective | TaN Modification |
|---|---|---|
| | Layer Process | Layer Process |
| Pressure (mTorr) | 55-75 | 5-15 |
| Ar Flow rate (sccm) | 498 | 215.5 |
| N₂ flow rate (sccm) | 15 | 34.5 |
| RF Power (Watts) | 5250 | 4500 |
| DC Power (Watts) | 1500 | 1635 |
| TS (mm) | 230 | 252 |
| BSP (Torr) | 6 | 6 |
| Bias Power (kw) | <1 | <1 |
| Time (sec) | 30 | 5-10 |

After the protective layer deposition process was complete, the iPVD system was restocked with a Ta target and any other materials necessary for the TaN surface modification process.

For the TaN surface modification process, the processing chamber of an iPVD system was operated according to the parameters show in Table 1 above. The result was a barrier layer of TaN over the patterned substrate with little-to-no overhang.

### Example 2

For a deposition process where the barrier layer material of TaN was followed with a second barrier layer material of Ta, the processing chamber of an iPVD system was prepared to perform a TaN protective layer process with a Ta target and the following parameters:

TABLE 2

| | TaN Protective | TaN Modification |
|---|---|---|
| | Layer Process | Layer Process |
| Pressure (mTorr) | 55-75 | 5-15 |
| Ar Flow rate (sccm) | 498 | 215.5 |
| N₂ flow rate (sccm) | 15 | 34.5 |
| RF Power (Watts) | 5250 | 4500 |
| DC Power (Watts) | 1500 | 1635 |
| TS (mm) | 230 | 252 |
| BSP (Torr) | 6 | 6 |
| Bias Power (kw) | <1 | <1 |
| Time (sec) | 30 | 5-10 |

After the first protective layer deposition process was complete, the iPVD system was restocked with a Ta target and any other materials necessary for the TaN surface modification process.

For the TaN first surface modification process, the processing chamber of an iPVD system was operated according to the parameters shown in Table 2 above.

After the first TaN surface modification process was complete, the iPVD system was again restocked with another Ta target and any other materials necessary for the second Ta protective layer deposition process with Ta deposited as the barrier layer material. Accordingly, the process chamber was operated with the following parameters:

TABLE 3

| | Ta Protective | Ta Modification |
|---|---|---|
| | Layer Process | Layer Process |
| Pressure (mTorr) | 55-75 | 5-15 |
| Ar Flow rate (sccm) | 513 | 250 |
| RF Power (Watts) | 5250 | 4500 |
| DC Power (Watts) | 1500 | 3400 |
| TS (mm) | 230 | 252 |
| BSP (Torr) | 6 | 6 |
| Bias Power (kw) | 0.200 | 0.800 |
| Time (sec) | 30 | 5-12 |

After the second Ta protective layer deposition process was complete, the iPVD system was restocked with a Ta target and any other materials necessary for the second Ta surface modification process.

For the second Ta surface modification process, the processing chamber of an iPVD system was operated according to the parameters shown in Table 3 above. The result was a first TaN barrier layer over the patterned substrate and a second Ta barrier layer over the first TaN barrier layer with little-to-no overhang.

### Example 3

For a deposition process where the barrier layer material of TaN was followed with a second barrier layer material of Ta, the processing chamber of an iPVD system was prepared to perform a TaN protective layer process with a Ta target and the following parameters:

TABLE 4

| | TaN Protective | TaN Modification |
|---|---|---|
| | Layer Process | Layer Process |
| Pressure (mTorr) | 55-75 | 5-15 |
| Ar Flow rate (sccm) | 498 | 215.5 |
| N₂ flow rate (sccm) | 15 | 34.5 |
| RF Power (Watts) | 5250 | 4500 |
| DC Power (Watts) | 1500 | 1635 |
| TS (mm) | 230 | 252 |
| BSP (Torr) | 6 | 6 |
| Bias Power (kw) | <1 | <1 |
| Time (sec) | 30 | 5-10 |

After the first TaN protective layer deposition process was complete, the iPVD system was restocked with a Ta target and any other materials necessary for the first TaN surface modification process and operated with the parameters shown in Table 4 above.

After the first TaN surface modification process was complete, the iPVD system was restocked with another Ta target and any other materials necessary for a second Ta surface modification process where the processing chamber of an iPVD system was operated according to the parameters shown in TABLE 5.

TABLE 5

| | Ta Modification Layer |
|---|---|
| Pressure (mTorr) | 5-15 |
| Ar Flow rate (sccm) | 250 |
| RF Power (Watts) | 4500 |
| DC Power (Watts) | 3400 |
| TS (mm) | 252 |
| BSP (Torr) | 6 |
| Bias Power (kw) | 0.800 |
| Time (sec) | 5-12 |

What is claimed is:

1. A method of operating an ionized physical vapor deposition system comprising:
positioning a patterned substrate on a wafer table within a vacuum processing chamber opposite a target of a layer material, the patterned substrate having a field area and one or more features each having at least one sidewall and at least one bottom surface; and
performing a layer forming process by creating in the vacuum processing chamber an inductively-coupled high-density plasma that includes a plurality of ions of a process gas, and with the inductively-coupled high-density plasma sputtering the layer material from the target, ionizing the sputtered layer material for depositing the ionized layer material as a field layer onto the field area of the patterned substrate, and etching the field layer from the patterned substrate,
wherein the performing of the layer forming process includes establishing a chamber pressure and maintaining a substrate bias power effective to establish a gross deposition rate on the field layer of greater than about 25 nm/min and less than about 70 nm/min while simultaneously etching the field layer from the field area such that the field layer is deposited on the field area at a field area net deposition rate that is greater than about −10 nm/min and less than about +40 nm/min.

2. The method according to claim 1, wherein the chamber pressure is greater than about 5 mTorr and less than about 15 mTorr.

3. The method according to claim 1, wherein the layer forming process is a net deposition process wherein the field area net deposition rate is greater than about 5 nm/min.

4. The method according to claim 3, wherein the layer forming process is preceded by a deposition process step that deposits the layer material without etching a surface on which the layer material is being deposited.

5. The method according to claim 1, wherein the layer forming process is preceded by a deposition process step that deposits the layer material without etching a surface on which the layer material is being deposited.

6. The method according to claim 1, wherein the sputtering of the layer material includes confining electrons within the inductively-coupled high-density plasma against the target in a magnetic field formed by a permanent magnet pack located in a fixed position behind the target and having a static magnetic field extending between the target and the wafer table and having a static magnetic field strength of at least 20 Gauss at the target surface and of not more than about 10 Gauss at the wafer table surface.

7. The method according to claim 1, wherein:
a substrate bias power is provided at less than about 1 kW;
an RF power is provided that ranges from about 4 kW to about 5.25 kW;
a target DC power is provided that ranges from about 0.5 kW to about 3 kW;
a substrate-to-target distance is provided that ranges from about 240 mm to about 255 mm;
a back-side gas is provided between the patterned substrate and the wafer table at a pressure in a range of from about 4 Torr to about 20 Torr; and
wherein the performing of the layer forming process occurs for a process time of greater than about 5 seconds and less than about 15 seconds.

8. The method according to claim 1, wherein the layer forming process is a surface modification process and the method further comprises:
performing a protective layer deposition process prior to performing the surface modification process to establish a field layer on the field area, a sidewall layer on each sidewall, and a bottom layer on each bottom surface, by adjusting the chamber pressure and the substrate bias power to establish a field deposition rate of greater than about 5 nm/min and less than about 30 nm/min of the field layer, a sidewall deposition rate of greater than 2 nm/min of the sidewall layer, and a bottom deposition rate of greater than 2 nm/min of the bottom layer.

9. The method according to claim 8, wherein the chamber pressure is greater than about 55 mTorr and less than about 100 mTorr during the protective layer deposition process.

10. The method according to claim 1, wherein:
the performing of the layer forming process is carried out without substantially exposing a surface on which the layer material is being deposited to ions having energies exceeding the sputter threshold of said surface.

11. A method of operating an ionized physical vapor deposition system comprising a vacuum processing chamber and an antenna external to the vacuum processing chamber, the method comprising:
positioning a patterned substrate on a wafer table within the vacuum processing chamber opposite a target of a coating material, the patterned substrate having a field area and one or more features each having at least one sidewall and at least one bottom surface;
creating in the processing chamber an inductively-coupled high-density plasma that includes a plurality of ions of a process gas, and with the inductively-coupled high-density plasma sputtering the coating material from the target and ionizing the sputtered coating material for depositing the ionized coating material onto the patterned substrate;
performing a protective layer deposition process to establish a field layer on the field area, a sidewall layer on each sidewall, and a bottom layer on each bottom surface, by adjusting the substrate bias power to establish a field deposition rate of greater than about 5 nm/min and less than about 30 nm/min of the field layer and without etching an underlying surface of the patterned substrate onto which the protective layer is being deposited; and
performing a surface modification process to establish a modified field layer on the field area by adjusting the substrate bias power effective to establish a gross deposition rate of the modified field layer of greater than about 25 nm/min and less than about 70 nm/min while simultaneously etching the modified field layer from the field area such that the modified field layer is deposited on the field area at a field modification net deposition rate that is greater than about −10 nm/min and less than about +40 nm/min.

12. The method according to claim 11, wherein the performing of the protective layer deposition process includes adjusting a chamber pressure to greater than about 55 mTorr and less than about 100 mTorr and the performing of the surface modification process includes adjusting the chamber pressure to greater than about 5 mTorr and less than about 15 mTorr.

13. The method according to claim 11, wherein the field modification net deposition rate is greater than about 5 nm/min.

14. The method according to claim 11, wherein performing of the protective layer deposition process further comprises:
adjusting a first RF power, a first target DC power, a first substrate-to-target distance, or the substrate bias power, or a combination thereof, to establish the field deposition rate;
wherein the first RF power ranges from about 4 kW to about 5.5 kW, the first target DC power ranges from about 0.5 kW to about 3 kW, and the substrate bias power is less than about 1 kW during the protective layer deposition process.

15. The method according to claim 11, wherein performing of the surface modification process further comprises:
adjusting a second RF power, a second target DC power, a second substrate-to-target distance, or the substrate bias power, or a combination thereof, to establish the field modification net deposition rate;
wherein the second RF power ranges from about 4 kW to about 5.5 kW, the second target DC power ranges from about 0.5 kW to about 3 kW, and the substrate bias power is less than about 1 kW during the surface modification process.

16. The method according to claim 11, wherein the method further comprises:
configuring a permanent magnet pack in a fixed position behind the target; and
providing a static magnetic field extending between the target and the wafer table, the static magnetic field having a static magnetic field strength of at least 20 Gauss at a target surface and less than about 10 Gauss at the substrate.

17. The method according to claim 11, wherein the coating material is tantalum (Ta), ruthenium (Ru), or copper (Cu).

18. The method according to claim 17, where the coating material is Ta and the Ta reacts with a nitrogen-containing gas to form a TaN layer on the patterned substrate.

19. The method according to claim 11, wherein a modified field layer thickness is about 1 nm to about 10 nm after the surface modification process, a modified sidewall layer thickness is from about 1 nm to about 6 nm after the surface modification process, and a modified bottom layer thickness is from about 0 nm to about 2 nm after the surface modification process.

20. The method according to claim 11, further comprising:
performing a second protective layer deposition process to establish a second field layer on the field area, a second sidewall layer on each sidewall, and a second bottom layer on the bottom surface, by adjusting the chamber pressure to greater than about 55 mTorr and less than about 100 mTorr and adjusting the substrate bias power to establish a second field deposition rate of greater than about 5 nm/min and less than about 30 nm/min of the second field layer.

21. The method according to claim 20, further comprising:
performing a second surface modification process to establish a second modified field layer on the field area by adjusting the chamber pressure to greater than about 5 mTorr and less than about 15 mTorr and adjusting the substrate bias power effective to establish a second gross deposition rate of the second modified field layer of greater than about 25 nm/min and less than about 70 nm/min while simultaneously etching the second modified field layer from the field area such that the second modified field layer is deposited on the field area at a second field modification net deposition rate that is greater than about −10 nm/min and less than about +40 nm/min.

22. The method according to claim 11, further comprising:
performing a second surface modification process to establish a second modified field layer on the field area by adjusting the chamber pressure to greater than about 5 mTorr and less than about 15 mTorr and adjusting the substrate bias power effective to establish a second gross deposition rate of the second modified field layer of greater than about 25 nm/min and less than about 70 nm/min while simultaneously etching the second modified field layer from the field area such that the second modified field layer is deposited on the field area at a second field modification net deposition rate that is greater than about −10 nm/min and less than about +40 nm/min.

23. The method according to claim 11, wherein:
the performing of the protective layer deposition process is carried out to deposit a barrier layer material onto a low-K dielectric on the substrate without substantially exposing the dielectric to ions having energies exceeding the sputter threshold of the dielectric.

24. A method of operating an ionized physical vapor deposition system comprising a vacuum processing chamber and an antenna external to the vacuum processing chamber, the method comprising:
positioning a patterned substrate on a wafer table within the vacuum processing chamber opposite a target of a barrier layer material, the patterned substrate having a field area and one or more features each having a sidewall area and a bottom surface area;
performing a first protection layer deposition process to establish a field barrier layer on the field area, a sidewall barrier layer on each sidewall area, and a bottom barrier layer on each bottom surface area, wherein a first substrate bias power is adjusted to establish a field deposition rate of the field barrier layer, a sidewall deposition rate of the sidewall barrier layer, or a bottom deposition rate of the bottom barrier layer, or any combination thereof, the field deposition rate of the field barrier layer being greater than about 5 nm/min and less than about 30 nm/min, the sidewall deposition rate of the sidewall barrier layer being greater than about 2 nm/min and less than about 10 nm/min, and the bottom deposition rate of the bottom barrier layer being greater than about 2 nm/min and less than about 10 nm/min, wherein a first chamber pressure is established in the vacuum processing chamber, a first RF power is provided to the antenna, and a first DC power is simultaneously provided to the target during the first protection layer deposition process, the first chamber pressure ranges from about 55 mTorr to about 75 mTorr; and
performing a first surface modification process to establish a modified field barrier layer on the field area, a modified sidewall barrier layer on each sidewall area, and a modified bottom barrier layer on each bottom surface area, wherein a second substrate bias power is adjusted to establish a field modification rate of the modified field barrier layer, a sidewall modification rate of the modified sidewall barrier layer, or a bottom modification rate of the modified bottom barrier layer, or any combination thereof, the field modification rate of the modified field barrier layer ranges from about −5 nm/min to about −0.5 nm/min, the sidewall modification rate of the modified sidewall barrier layer ranges from about 0 nm/min to about 2 nm/min, and the bottom modification rate of the modified bottom barrier layer ranges from about −2 nm/min to about 1 nm/min, wherein a second chamber pressure is established in the vacuum processing chamber, a second RF power is provided to the antenna, and a second DC power is simultaneously provided to the target during the first surface modification process, the second chamber pressure ranges from about 5 mTorr to about 15 mTorr.

25. The method of claim 24, wherein the first RF power ranges from about 5000 watts to about 5500 watts, and the first DC power ranges from about 1700 watts to about 3000 watts.

26. The method of claim 25, wherein the second RF power ranges from about 4200 watts to about 4800 watts, and the second DC power ranges from about 1400 watts to about 1800 watts.
